(19) United States
(12) Patent Application Publication
(10) Pub. No.: US 2024/0324163 A1
(43) Pub. Date: Sep. 26, 2024

(54) SEMICONDUCTOR DEVICE AND SEMICONDUCTOR STORAGE DEVICE

(71) Applicant: Kioxia Corporation, Tokyo (JP)

(72) Inventors: Takayuki TSUKAGOSHI, Kawasaki Kanagawa (JP); Daichi SUGAWARA, Yokkaichi Mie (JP)

(21) Appl. No.: 18/590,867

(22) Filed: Feb. 28, 2024

(30) Foreign Application Priority Data
Mar. 20, 2023 (JP) 2023-043819

(51) Int. Cl. H10B 10/00; H01L 29/786

(52) U.S. Cl. CPC H10B 10/125; H01L 29/7869

(57) ABSTRACT

A semiconductor device includes an insulating layer, an oxide semiconductor therein and extending in a first direction, a first electrode on an upper end of the semiconductor, a second electrode on a lower end thereof, and a gate electrode in the insulating layer and surrounding the oxide semiconductor. The semiconductor includes a first portion including the upper end, a second portion between the first portion and the lower end, and a first boundary portion between the first and second portions. An upper end of the first portion has a first diameter, a lower end of the first portion has a second diameter equal to or smaller than the first diameter, a lower end of the first boundary portion has a third diameter smaller than the second diameter, and a lower end of the second portion has a fourth diameter equal to or smaller than the third diameter.

### CROSS-REFERENCE TO RELATED APPLICATION

This application is based upon and claims the benefit of priority from Japanese Patent Application No. 2023-043819, filed Mar. 20, 2023, the entire contents of which are incorporated herein by reference.

### FIELD

Embodiments described herein relate generally to a semiconductor device and a semiconductor storage device.

### BACKGROUND

Some semiconductor elements are formed of an oxide semiconductor.

### BRIEF DESCRIPTION OF THE DRAWINGS

FIG. 1 is a circuit diagram illustrating a circuit configuration of a memory cell array according to a first embodiment.

FIG. 2 is a schematic cross-sectional view illustrating a structure of a semiconductor storage device according to the first embodiment, and shows a part of a cross section parallel to a YZ plane.

FIG. 3 is a schematic cross-sectional view illustrating a semiconductor device according to the first embodiment, and shows a cross section including an extension axis of an oxide semiconductor layer.

FIG. 4 is a schematic cross-sectional view illustrating a semiconductor device according to the first embodiment, and shows a cross section parallel to an XY plane.

FIG. 5 is a schematic view showing a manufacturing process of the semiconductor device according to the first embodiment.

FIG. 6 is a schematic view showing the manufacturing process of the semiconductor device according to the first embodiment.

FIG. 7 is a schematic view showing the manufacturing process of the semiconductor device according to the first embodiment.

FIG. 8 is a schematic view showing the manufacturing process of the semiconductor device according to the first embodiment.

FIG. 9 is a schematic view showing the manufacturing process of the semiconductor device according to the first embodiment.

FIG. 10 is a schematic view showing the manufacturing process of the semiconductor device according to the first embodiment.

FIG. 11 is a schematic view showing the manufacturing process of the semiconductor device according to the first embodiment.

FIG. 12 is a schematic view showing the manufacturing process of the semiconductor device according to the first embodiment.

FIG. 13 is a schematic view showing the manufacturing process of the semiconductor device according to the first embodiment.

FIG. 14 is a schematic view showing the manufacturing process of the semiconductor device according to the first embodiment.

FIG. 15 is a schematic view showing the manufacturing process of the semiconductor device according to the first embodiment.

FIG. 16 is a schematic view showing the manufacturing process of the semiconductor device according to the first embodiment.

FIG. 17 is a schematic view showing the manufacturing process of the semiconductor device according to the first embodiment.

FIG. 18 is a schematic view showing the manufacturing process of the semiconductor device according to the first embodiment.

FIG. 19 is a schematic view showing the manufacturing process of the semiconductor device according to the first embodiment.

FIG. 20 is a schematic view showing the manufacturing process of the semiconductor device according to the first embodiment.

FIG. 21 is a schematic view showing the manufacturing process of the semiconductor device according to the first embodiment.

FIG. 22 is a schematic view showing the manufacturing process of the semiconductor device according to the first embodiment.

FIG. 23 is a schematic view showing the manufacturing process of the semiconductor device according to the first embodiment.

FIG. 24 is a schematic view showing the manufacturing process of the semiconductor device according to the first embodiment.

FIG. 25 is a schematic view showing the manufacturing process of the semiconductor device according to the first embodiment.

FIG. 26 is a schematic view showing the manufacturing process of the semiconductor device according to the first embodiment.

FIG. 27 is a diagram showing a change with respect to a constriction amount in the on-state current flowing on the surface of the oxide semiconductor layer according to the first embodiment.

FIG. 28 is a diagram showing a change with respect to the constriction amount in a threshold voltage of a field effect transistor according to the first embodiment.

FIG. 29 is a schematic cross-sectional view showing a semiconductor device according to a second embodiment, and shows a cross section including an extension axis of the oxide semiconductor layer.

FIG. 30 is a schematic view showing a manufacturing process of the semiconductor device according to the second embodiment.

FIG. 31 is a schematic view showing the manufacturing process of the semiconductor device according to the second embodiment.

FIG. 32 is a schematic view showing the manufacturing process of the semiconductor device according to the second embodiment.

FIG. 33 is a schematic view showing the manufacturing process of the semiconductor device according to the second embodiment.

FIG. 34 is a schematic view showing the manufacturing process of the semiconductor device according to the second embodiment.

FIG. 35 is a schematic view showing the manufacturing process of the semiconductor device according to the second embodiment.

FIG. 36 is a schematic view showing the manufacturing process of the semiconductor device according to the second embodiment.

FIG. 37 is a schematic view showing the manufacturing process of the semiconductor device according to the second embodiment.

FIG. 38 is a schematic view showing the manufacturing process of the semiconductor device according to the second embodiment.

FIG. 39 is a schematic view showing the manufacturing process of the semiconductor device according to the second embodiment.

FIG. 40 is a schematic view showing the manufacturing process of the semiconductor device according to the second embodiment.

FIG. 41 is a schematic view showing the manufacturing process of the semiconductor device according to the second embodiment.

FIG. 42 is a schematic cross-sectional view illustrating a modification example of the semiconductor device according to the first embodiment, and shows a cross section including the extension axis of the oxide semiconductor layer.

FIG. 43 is a schematic cross-sectional view illustrating the modification example of the semiconductor device according to the first embodiment, and shows a cross section including the extension axis of the oxide semiconductor layer.

### DETAILED DESCRIPTION

In the oxide semiconductor in the related art, the concentration of oxygen deficiency, which is a donor, is often high. Therefore, in a case where the oxide semiconductor is used in the channel of the field effect transistor, the threshold voltage becomes negative, and the characteristics of normally-on are obtained.

Embodiments provide a semiconductor device and a semiconductor storage device capable of increasing a threshold voltage.

In general, according to one embodiment, a semiconductor device comprises: an insulating layer; an oxide semiconductor formed in the insulating layer and extending in a first direction; a first electrode in contact with an upper end of the oxide semiconductor; a second electrode in contact with a lower end of the oxide semiconductor; and a gate electrode formed in the insulating layer and surrounding a part of the oxide semiconductor via an insulating film. The oxide semiconductor includes: a first portion including the upper end of the oxide semiconductor, a second portion between the first portion and the lower end of the oxide semiconductor, and a first boundary portion between the first and second portions. An upper end of the first portion has a first diameter, a lower end of the first portion and an upper end of the first boundary portion have a second diameter equal to or smaller than the first diameter, a lower end of the first boundary portion and an upper end of the second portion have a third diameter smaller than the second diameter, and a lower end of the second portion has a fourth diameter equal to or smaller than the third diameter. From the upper end of the oxide semiconductor toward the lower end thereof, a reduction rate of a diameter of the first boundary portion is larger than a reduction rate of a diameter of each of the first portion and the second portion.

Hereinafter, embodiments will be described with reference to the drawings. In order to facilitate understanding of the description, the same elements are designated by the same reference numerals as much as possible in each drawing, and duplicate description is omitted.

### FIRST EMBODIMENT

A configuration of a semiconductor storage device 101 according to a first embodiment will be described. Each drawing may show an X-axis, a Y-axis, and a Z-axis. The X-axis, the Y-axis, and the Z-axis form a three-dimensional right-handed orthogonal coordinates. Hereinafter, the arrow direction of the X-axis may be referred to as the X-axis+direction, and the opposite direction to the arrow may be referred to as the X-axis−direction, and the same applies to other axes. The Z-axis+direction and the Z-axis−direction may also be referred to as an “upper side” and a “lower side”, respectively. In addition, a plane orthogonal to each of the X-axis, the Y-axis, or the Z-axis may be referred to as a YZ plane, a ZX plane, or an XY plane. In addition, the Z-axis direction may be referred to as an “up-down direction”. The terms “upper side”, “lower side”, and “up-down direction” are terms indicating a relative positional relationship in the drawing, and are not terms for determining an orientation based on a vertical direction.

In the present specification, the term “connection” includes not only a physical connection but also an electrical connection, and includes not only a direct connection but also an indirect connection, unless otherwise specified.

The semiconductor storage device 101 according to the first embodiment is an oxide semiconductor-random access memory (OS-RAM) and includes a memory cell array.

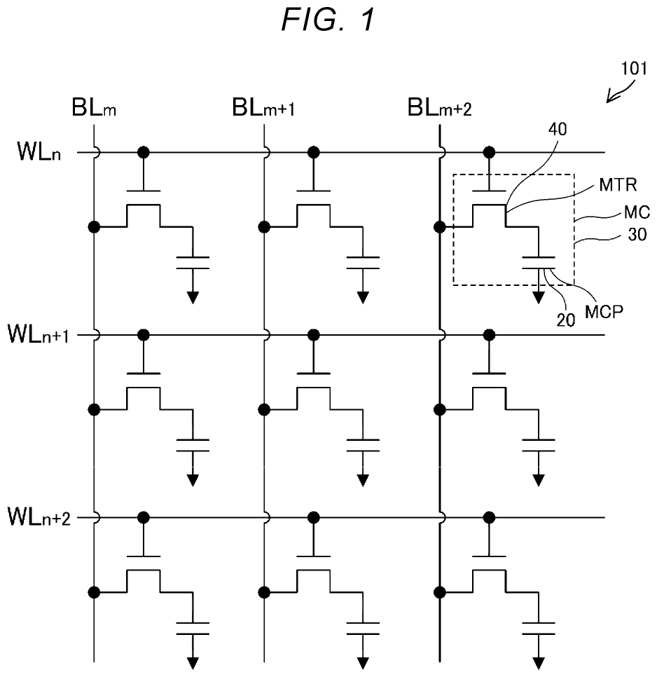

As shown in FIG. 1, the memory cell array includes a plurality of memory cells MC, a plurality of word lines WL, and a plurality of bit lines BL.

In FIG. 1, as an example of the plurality of word lines WL, a word line WLn, a word line WLn+1, and a word line WLn+2 are shown (here, n is a positive integer). In addition, in FIG. 1, as an example of the bit line BL, a bit line BLm, a bit line BLm+1, and a bit line BLm+2 are shown (here, m is a positive integer). The number of the plurality of memory cells MC is not limited to the number shown in FIG. 1.

The plurality of memory cells MC are arranged in a matrix shape, for example, to form a memory cell array. Each memory cell MC includes a memory transistor MTR which is a field effect transistor (FET) and a memory capacitor MCP.

A series of memory cells MC provided along the row direction are connected to a word line WL (for example, a word line WLn) corresponding to a row (for example, an n-th row) to which the memory cells MC belong. A series of memory cells MC provided along the column direction are connected to the bit line BL (for example, the bit line BLm+2) corresponding to the column (for example, the m+2-th column) to which the memory cells MC belong.

Specifically, the gate of the memory transistor MTR provided in the memory cell MC is connected to the word line WL corresponding to the row to which the memory cell MC belongs. One of the source and the drain of the memory transistor MTR is connected to the bit line BL corresponding to the column to which the memory cell MC belongs.

One electrode of the memory capacitor MCP provided in the memory cell MC is connected to the other of the source and the drain of the memory transistor MTR provided in the memory cell MC. The other electrode of the memory cell MC is connected to a power supply line (not shown) that applies a specific voltage.

The memory cell MC is capable of storing data by accumulating charges in the memory capacitor MCP with a current flowing through the corresponding bit line BL by switching of the memory transistor MTR based on the potential of the corresponding word line WL.

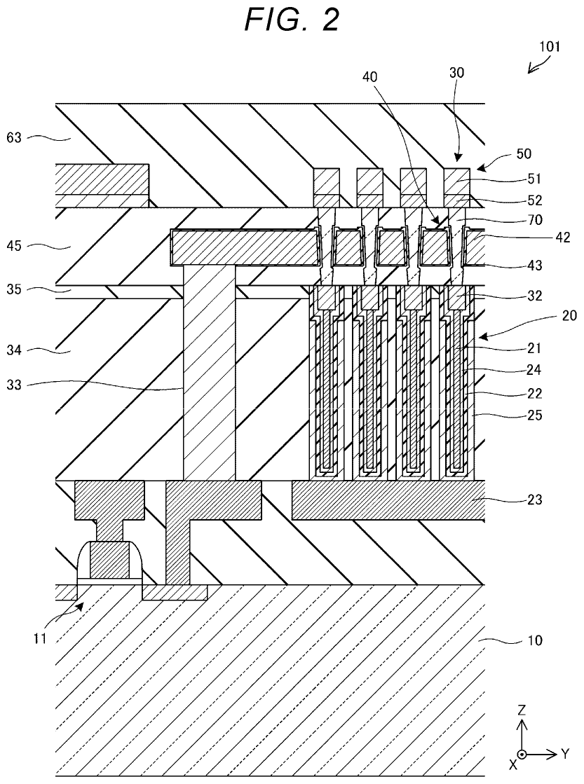

As shown in FIG. 2, the semiconductor storage device 101 includes a semiconductor substrate 10, a circuit 11, a capacitor 20, a semiconductor device 30, a conductor 33, and insulating layers 34, 35, 45, and 63.

The capacitor 20 includes a conductor 21, an insulating film 22 (e.g., a dielectric film), a conductor 23, a capacitor electrode 24, and a capacitor electrode 25.

The semiconductor device 30 includes a field effect transistor 40, an upper electrode 50 provided on the upper side of the field effect transistor 40, and an ITO layer 32 provided on the lower side of the field effect transistor 40. The upper electrode 50 includes a conductive layer 51 made of tungsten (W), titanium nitride (TiN), or the like and an ITO layer 52.

The field effect transistor 40 includes an oxide semiconductor layer 70 corresponding to a channel, a conductive layer 42 corresponding to a gate electrode, and a gate insulating film 43 provided between the conductive layer 42 and the oxide semiconductor layer 70.

The circuit 11 is a peripheral circuit such as a decoder for selecting a predetermined memory cell MC among the plurality of memory cells MC of the semiconductor storage device 101, that is, the capacitor 20 and the field effect transistor 40, a sense amplifier connected to the bit line BL, and a register including a static random-access memory (SRAM). The circuit 11 may include a complementary metal-oxide semiconductor (CMOS) circuit having a field effect transistor of a P-channel type field effect transistor (Pch-FET) and an N-channel type field effect transistor (Nch-FET), which are formed by a CMOS process.

The field effect transistor of the circuit 11 can be formed using, for example, a semiconductor substrate 10 such as a single crystal silicon substrate. The Pch-FET and the Nch-FET are so-called horizontal field effect transistors having a channel region, a source region, and a drain region in the semiconductor substrate 10, and having a channel for causing a carrier to flow in the X-axis direction or the Y-axis direction substantially parallel to the surface of the semiconductor substrate 10 in a region close to the surface of the semiconductor substrate 10. The semiconductor substrate 10 may have a conductive type of P-type or N-type. For convenience, FIG. 2 shows an example of the field effect transistor of the circuit 11.

The capacitor 20 is a memory capacitor MCP provided in the memory cell MC (see FIG. 1). Although four capacitors 20 are shown in FIG. 2, the number of capacitors 20 is not limited to four.

In the present embodiment, the capacitor 20 is provided on the upper side of the semiconductor substrate 10. The capacitor electrode 24 in the capacitor 20 is connected to the conductor 21 and the ITO layer 32. The capacitor electrode 25 faces the capacitor electrode 24. The insulating film 22 is provided between the capacitor electrode 24 and the capacitor electrode 25.

The capacitor 20 is a three-dimensional capacitor such as a pillar-type capacitor. As the capacitor of the present embodiment, another capacitor having a configuration capable of accumulating charges may be adopted.

The conductor 21 has a shape that is in contact with the end surface of the ITO layer 32 on the lower side and extends from the end portion toward the lower side. The capacitor electrode 24 covers the ITO layer 32 and the conductor 21. The insulating film 22 covers the capacitor electrode 24. The capacitor electrode 25 has a lower end that surrounds a part of the insulating film 22 on the lower side and is in contact with an end surface of the conductor 23 on the upper side.

The conductor 21 may contain a material such as amorphous silicon. The insulating film 22 may contain a material such as hafnium oxide. The conductor 23 and the capacitor electrodes 24 and 25 may contain materials such as tungsten (W) and titanium nitride (TiN).

The conductor 33 includes a wiring that electrically connects the circuit 11 and the semiconductor device 30. The conductor 33 may include a via wiring, and for example, as shown in FIG. 2, has a via wiring that extends in the Z-axis direction and connects the word line WL and the circuit 11 provided on the semiconductor substrate 10. The conductor 33 contains, for example, copper.

The insulating layer 34 is provided between the plurality of capacitors 20. The insulating layer 34 is, for example, a silicon oxide film containing silicon and oxygen.

The insulating layer 35 is provided on the upper side of the insulating layer 34. The insulating layer 35 is, for example, a silicon nitride film containing silicon and nitrogen.

The semiconductor device 30 is provided on the upper side of the capacitor 20. The ITO layer 32 in the semiconductor device 30 contains a metal oxide such as indium-tin-oxide (ITO).

The field effect transistor 40 corresponds to the memory transistor MTR of the memory cell MC (see FIG. 1). The field effect transistor 40 is provided on the upper side of the ITO layer 32.

The oxide semiconductor layer 70 of the field effect transistor 40 is located on the ITO layer 32 in a direction away from the semiconductor substrate 10, that is, on the upper side. The ITO layer 52 is located on the oxide semiconductor layer 70 in a direction away from the semiconductor substrate 10, that is, on the upper side. With such a configuration, the field effect transistor 40 is a so-called vertical transistor having a channel extending in the Z-axis direction (i.e., the up-down direction) substantially perpendicular to the surface of the semiconductor substrate 10.

In addition, the oxide semiconductor layer 70 is a semiconductor in which oxygen deficiency acts as a donor, and contains indium (In), zinc (Zn), and gallium (Ga) as metal elements. Specifically, the oxide semiconductor layer 70 is an oxide of indium, gallium, and zinc, that is, IGZO (InGaZnO). The oxide semiconductor layer 70 may be another type of oxide semiconductor.

The oxide semiconductor layer 70 is formed in the insulating layer 45 and is a columnar body extending in the Z-axis direction, that is, the up-down direction. The oxide semiconductor layer 70 forms a channel of the field effect transistor 40. The oxide semiconductor layer 70 has an amorphous structure.

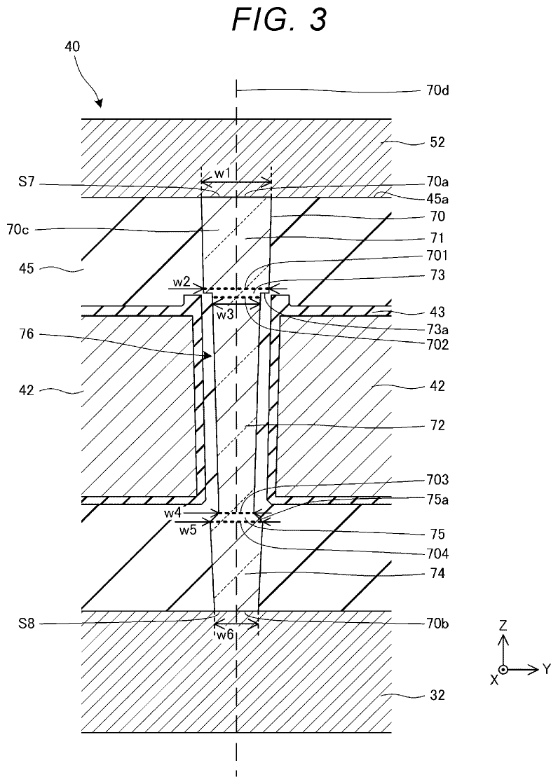

FIG. 3 shows a vertical cross section 70c of the oxide semiconductor layer 70. The vertical cross section 70c extends along the up-down direction. The vertical cross section 70c provides the extension axis 70d of the oxide semiconductor layer 70. The vertical cross section 70c is parallel to, for example, the YZ plane.

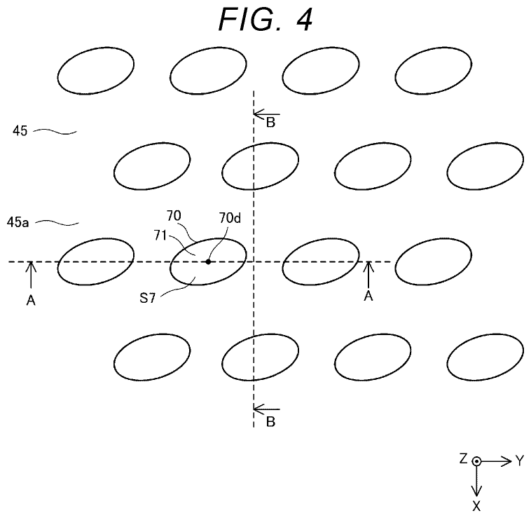

FIG. 4 shows a schematic cross-sectional view of the semiconductor storage device 101 when viewing the horizontal cross section 45a from the upper side. The horizontal cross section 45a is a cross section located at the boundary surface between the ITO layer 52 and the insulating layer 45 and parallel to the XY plane (hereinafter, may be referred to as a horizontal cross section).

The extension axis 70d is an axis passing through one point in a cross section parallel to the XY plane at the upper end 70a of the oxide semiconductor layer 70 (hereinafter, may be referred to as an upper end cross section) and one point in a cross section parallel to the XY plane at the lower end 70b of the oxide semiconductor layer 70 (hereinafter, may be referred to as a lower end cross section). Specifically, the extension axis 70d is, for example, an axis passing through the center point of the upper end cross section and the center point of the lower end cross section.

In the present embodiment, the shape of the horizontal cross section of the oxide semiconductor layer 70 is an ellipse. The shape of the horizontal cross section of the oxide semiconductor layer 70 may be a circle or may be another shape.

As shown in FIGS. 3 and 4, the ITO layer 52 of the upper electrode 50 is connected to the upper end 70a of the oxide semiconductor layer 70 and functions as one of the source or the drain of the field effect transistor 40. The ITO layer 32 is connected to the lower end 70b of the oxide semiconductor layer 70 and functions as the other of the source or the drain of the field effect transistor 40.

The oxide semiconductor layer 70 includes portions 71, 72, 73, 74, and 75. The portions 71, 73, 72, 75, and 74 are provided in this order from the upper side to the lower side in series. The portion 73 is a portion of the oxide semiconductor layer 70 at a boundary of the portions 71 and 72, and the portion 75 is a portion of the oxide semiconductor layer 70 at a boundary of the portions 72 and portion 74.

The shape of the vertical cross section 70c is constricted between the upper end 70a of the oxide semiconductor layer 70 and the lower end 70b of the oxide semiconductor layer 70. Specifically, the portions 72, 73, and 75 are constricted portions located between the upper end 70a and the lower end 70b.

The oxide semiconductor layer 70 is constricted around the entire circumference. That is, not only in the vertical cross section 70c parallel to the YZ plane, but also in the vertical cross section extending along the up-down direction and including the extension axis 70d (for example, a cross section including the extension axis 70d and parallel to the ZX plane), the shape is constricted between the upper end 70a and the lower end 70b as in the vertical cross section 70c.

The portion 71 in the oxide semiconductor layer 70 includes the upper end 70a and the first end 701 on the lower side. In the vertical cross section 70c, the size of the width (hereinafter, may be referred to as the horizontal width) in the direction (Y-axis direction) perpendicular to the up-down direction is w1 (an example of the “first value”) at the upper end 70a and is w2 (an example of the “second value”) equal to or smaller than w1 at the first end 701.

In the present embodiment, w2 is smaller than w1. The portion of the vertical cross section 70c provided in the portion 71 has the horizontal width monotonically decreasing from the upper side to the lower side. In addition, the portion of the vertical cross section 70c provided in the portion 71 may have a constant horizontal width. In this case, w2 and w1 are the same.

The portion 72 includes the second end 702 on the upper side and the third end 703 on the lower side. In the vertical cross section 70c, the size of the horizontal width is w3 smaller than w2 (an example of the “third value”) at the second end 702, and w4 equal to or smaller than w3 (an example of the “fourth value”) at the third end 703. The difference between w2 and w3 is, for example, 2 nm or more. The difference between w2 and w3 is more preferably 4 nm or more.

In the present embodiment, w4 is smaller than w3. The portion of the vertical cross section 70c provided in the portion 72 has the horizontal width monotonically decreasing from the upper side to the lower side. In addition, the portion of the vertical cross section 70c provided in the portion 72 may have a constant horizontal width. In this case, w4 and w3 are the same.

The portion 73 connects the portion 71 and the portion 72. Specifically, the end of the upper side of the portion 73 is connected to the first end 701 of the portion 71. The end of the lower side of the portion 73 is connected to the second end 702 of the portion 72.

In the present embodiment, the portion 73 has a stepped surface 73a (an example of a “first stepped surface”) facing the lower side. The stepped surface 73a is substantially parallel to the XY plane and is formed in an annular shape when viewed from on the lower side.

The end of the upper side of the portion 73, that is, the first end 701 need only be located on the upper side of the stepped surface 73a. The end of the lower side of the portion 73, that is, the second end 702 need only be located on the lower side of the stepped surface 73a. The distance between the first end 701 and the second end 702 may be extremely small and close to zero.

In the portion 73, in the vertical cross section 70c, the reduction ratio of the horizontal width to the increase amount of the distance from the upper end 70a (hereinafter, may be referred to as the horizontal width reduction ratio) is larger than the horizontal width reduction ratio of the vertical cross section 70c provided in the portion 71 and the horizontal width reduction ratio of the vertical cross section 70c provided in the portion 72.

The horizontal width reduction ratio of the portion of the vertical cross section 70c provided in the portion 73 is, for example, the horizontal width reduction ratio when the portion 73 is seen as a whole. Specifically, since the horizontal width is reduced from w2 to w3 while the distance from the upper end 70a increases from the first end 701 to the second end 702, the horizontal width reduction ratio is obtained by dividing a value obtained by subtracting w3 from w2 by a difference between the distance from the upper end 70a to the second end 702 and the distance from the upper end 70a to the first end 701.

Similarly, the horizontal width reduction ratio of the vertical cross section 70c provided in the portion 71 is, for example, the horizontal width reduction ratio when the portion 71 is seen as a whole. Specifically, the horizontal width reduction ratio is a value obtained by dividing a value obtained by subtracting w2 from w1 by a distance from the upper end 70a to the first end 701.

Similarly, the horizontal width reduction ratio of the vertical cross section 70c provided in the portion 72 is, for example, the horizontal width reduction ratio when the portion 72 is seen as a whole. Specifically, the horizontal width reduction ratio is a value obtained by dividing a value obtained by subtracting w3 from w4 by a difference between a distance from the upper end 70a to the third end 703 and a distance from the upper end 70a to the second end 702.

The portion 74 includes the fourth end 704 of the upper side and the lower end 70b. In the vertical cross section 70c, the size of the horizontal width is w5 larger than w4 at the fourth end 704 (an example of the “fifth value”), and is w6 equal to or smaller than w5 at the lower end 70b (an example of the “sixth value”). The magnitude of the difference between w5 and w4 is, for example, 2 nm or more. The difference between w5 and w4 is more preferably 4 nm or more.

In the present embodiment, w6 is smaller than w5. The portion of the vertical cross section 70c provided in the portion 74 has the horizontal width monotonically decreasing from the upper side to the lower side. In addition, the portion of the vertical cross section 70c provided in the portion 74 may have a constant horizontal width. In this case, w6 and w5 are the same.

The portion 75 connects the portion 72 and the portion 74. Specifically, the end of the upper side of the portion 75 is connected to the third end 703 of the portion 72. The end of the lower side of the portion 75 is connected to the fourth end 704 of the portion 74.

In the portion 75, in the vertical cross section 70c, the horizontal width increases with an increase in the distance from the upper end 70a.

Specifically, the portion 75 has a tapered surface 75a facing the upper side. The tapered surface 75a is a surface inclined at a predetermined angle with respect to the XY plane, and is a surface that approaches the upper end 70a as much as the portion close to the extension axis 70d. The tapered surface 75a is formed in an annular shape when viewed from the upper side. That is, the portion 75 has a tapered shape toward the upper side.

A part of the constricted portion has a cross-sectional area smaller than the area S7 of the upper end 70a and the area S8 of the lower end 70b. The entire constricted portion may have a cross-sectional area smaller than the area S7 and the area S8.

In addition, a part of the constricted portion has a horizontal width smaller than the horizontal width w1 and the horizontal width w6. The entire constricted portion may have a horizontal width smaller than the horizontal width w1 and the horizontal width w6.

The conductive layer 42 is formed in the insulating layer 45. A gate insulating film 43 is formed around the conductive layer 42. The gate insulating film 43 is, for example, a silicon nitride film (Si3N4) containing silicon and nitrogen, for example. The conductive layer 42 configures the gate electrode of the field effect transistor 40 and functions as a word line WL (see FIG. 1).

The conductive layer 42 surrounds a part of the oxide semiconductor layer 70 via the gate insulating film 43. In the present embodiment, the conductive layer 42 surrounds a part of the portion 72 via the gate insulating film 43, and does not surround the portions 71, 73, 74, and 75.

The conductive layer 42 may surround the entire portion 72. At this time, the conductive layer 42 may further surround at least one of a part of the portion 73 and a part of the portion 75. In addition, in the conductive layer 42, the entire portion 73 may be further surrounded or the entire portion 75 may be further surrounded in a case where a portion of the oxide semiconductor layer 70 is left without being surrounded.

### Manufacturing Method of Semiconductor Device

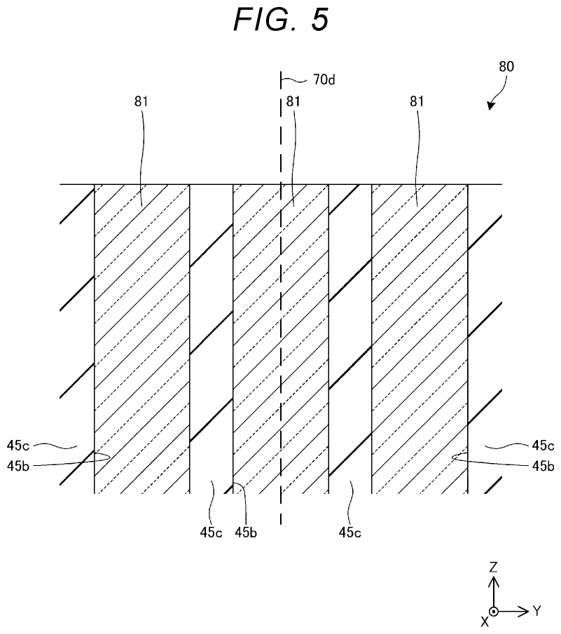

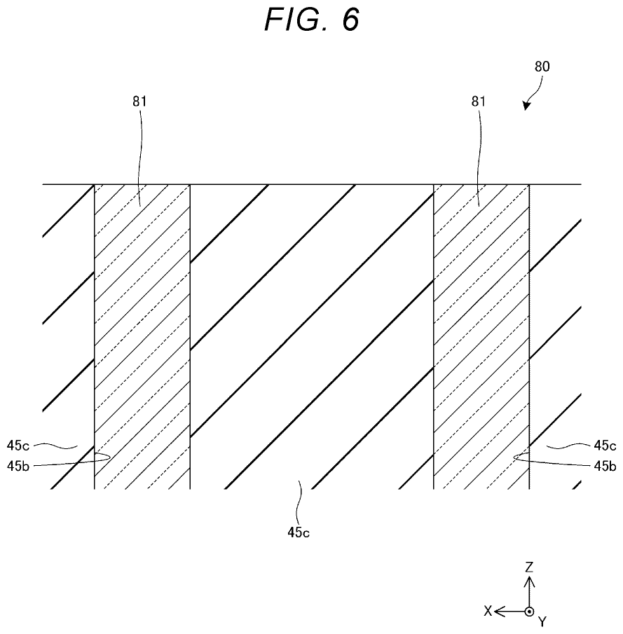

Hereinafter, a manufacturing method of the semiconductor device 30 will be described as an example of a manufacturing method of a semiconductor device according to the first embodiment. In FIGS. 5, 7, 9, 11, 13, 15, 17, 19, 21, 23, and 25, cross-sectional views taken along the cutting-line A-A shown in FIG. 4 are shown. In FIGS. 6, 8, 10, 12, 14, 16, 18, 20, 22, 24, and 26, cross-sectional views taken along the cutting-line B-B shown in FIG. 4 are shown.

First, as shown in FIGS. 5 and 6, a sacrificial amorphous silicon layer 81 extending in the up-down direction is formed. The sacrificial amorphous silicon layer 81 is formed in the hole portion 45b of the insulating layer 45c provided on the surface of the semiconductor chip 80 on the upper side. The insulating layer 45c corresponds to a part of the insulating layer 45 on the lower side (see FIG. 3). Then, the surface on the upper side of the insulating layer 45c of the semiconductor chip 80 is subjected to chemical mechanical polishing together with the surface of the sacrificial amorphous silicon layer 81 on the upper side.

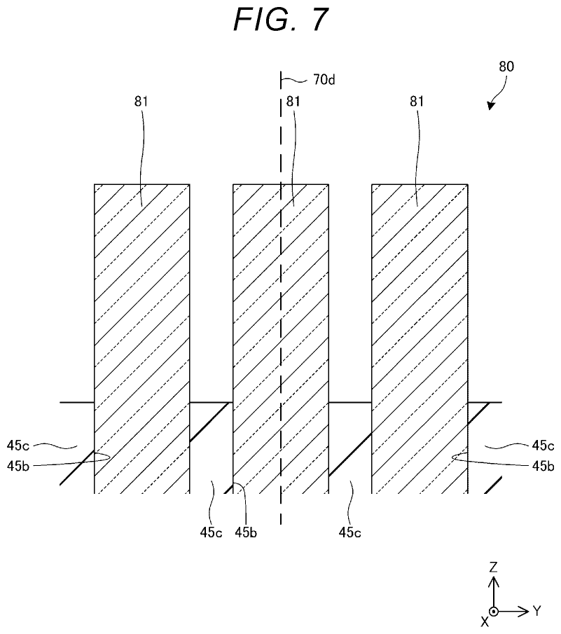

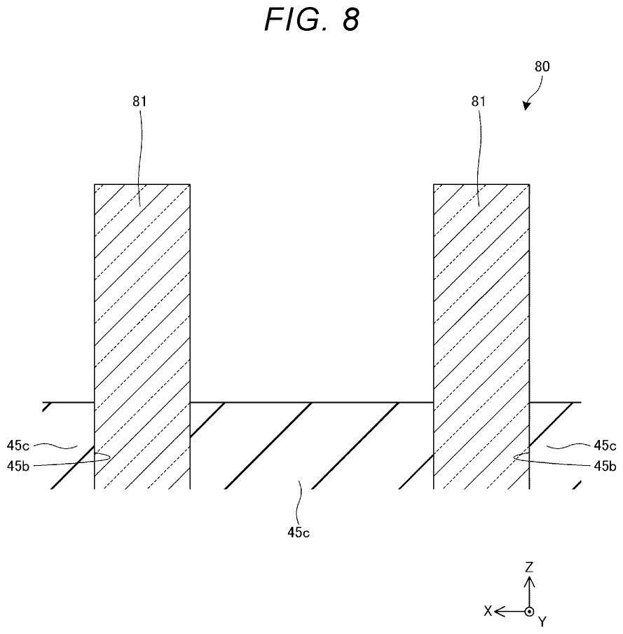

Next, as shown in FIGS. 7 and 8, the insulating layer 45c is subjected to an etch back, so that a part of the insulating layer 45c on the upper side is removed, and a part of the sacrificial amorphous silicon layer 81 on the upper side is exposed.

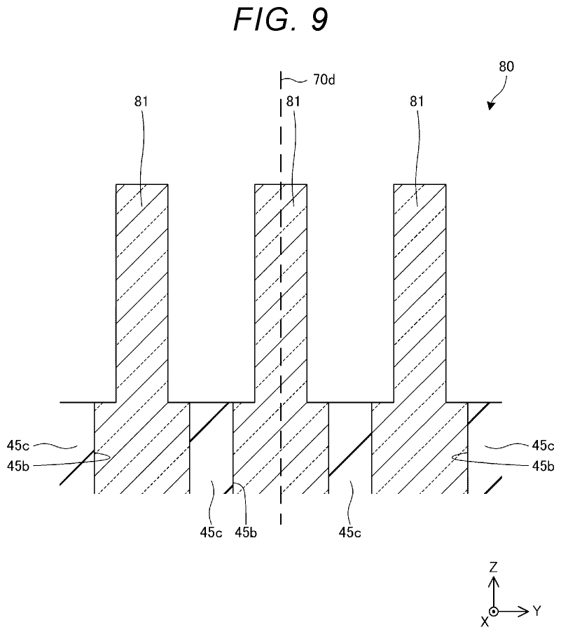

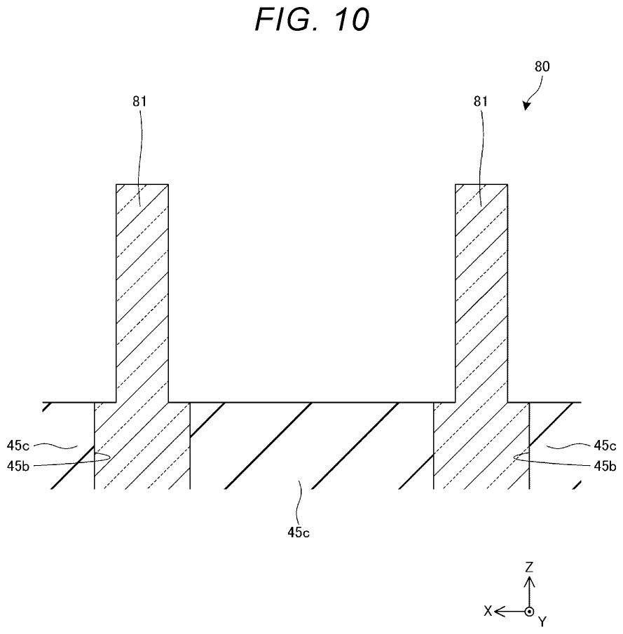

Next, as shown in FIGS. 9 and 10, the sacrificial amorphous silicon layer 81 is subjected to wet etching, so that the exposed portion of the sacrificial amorphous silicon layer 81 is reduced in diameter.

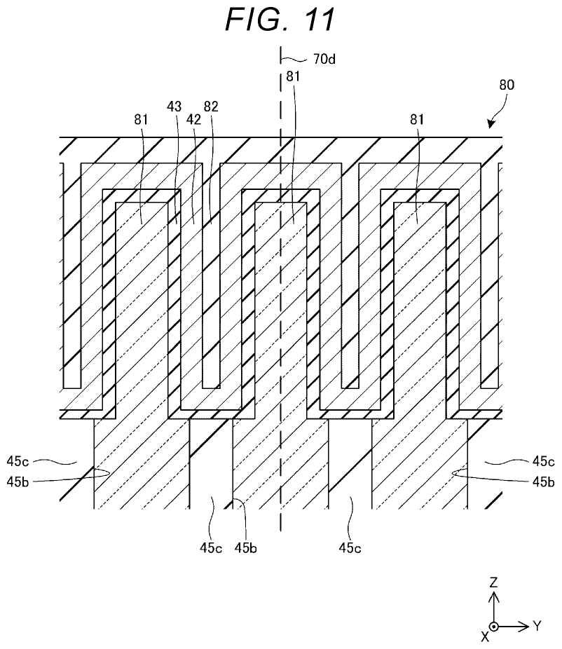

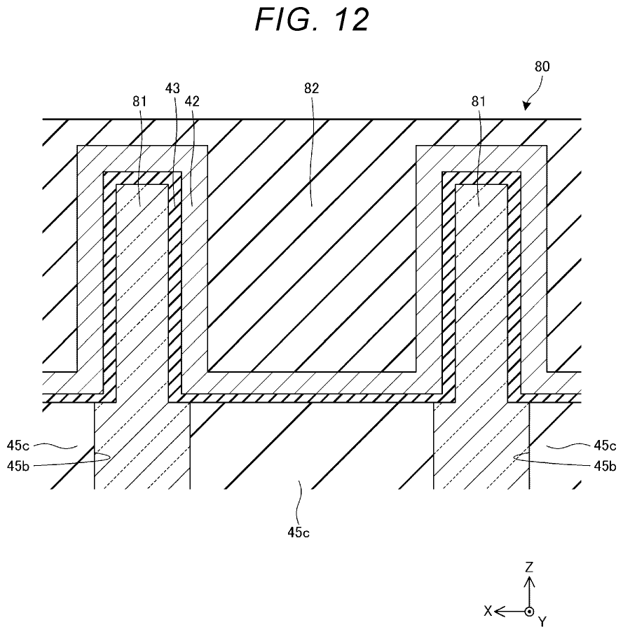

Next, as shown in FIGS. 11 and 12, the gate insulating film 43 is formed on the upper side of the exposed insulating layer 45c and the sacrificial amorphous silicon layer 81. The conductive layer 42 is formed on the upper side of the gate insulating film 43. Then, an insulating layer 82 made of SiO2 or the like is formed on the upper side of the conductive layer 42.

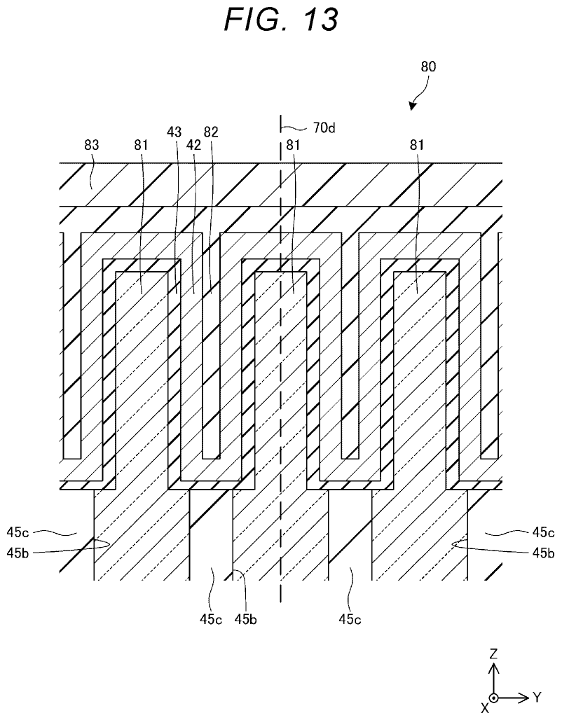

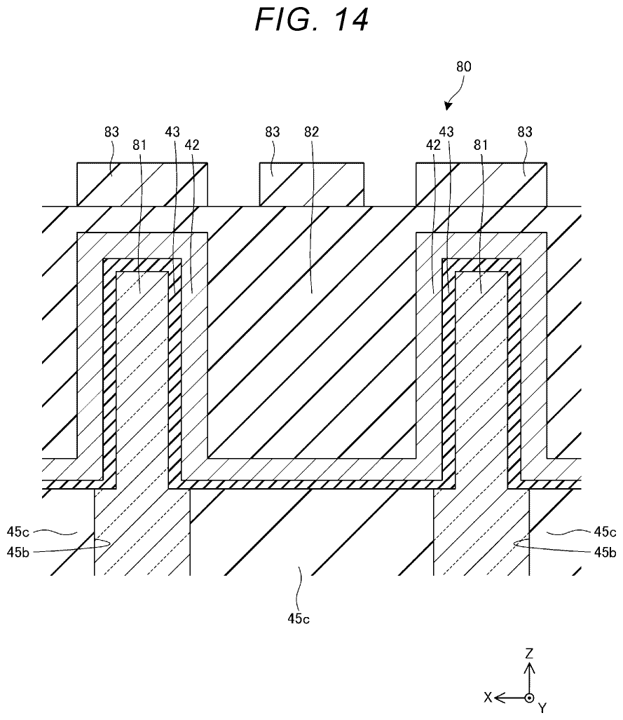

Next, as shown in FIGS. 13 and 14, a mask material 83 for processing word line is formed on the upper side of the insulating layer 82. Then, a part of the mask material 83 is removed by photolithography. Accordingly, a part of the insulating layer 82 is exposed.

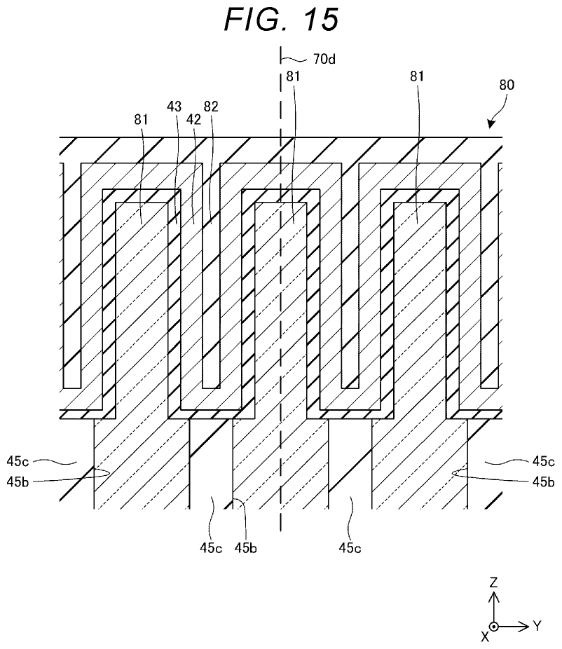

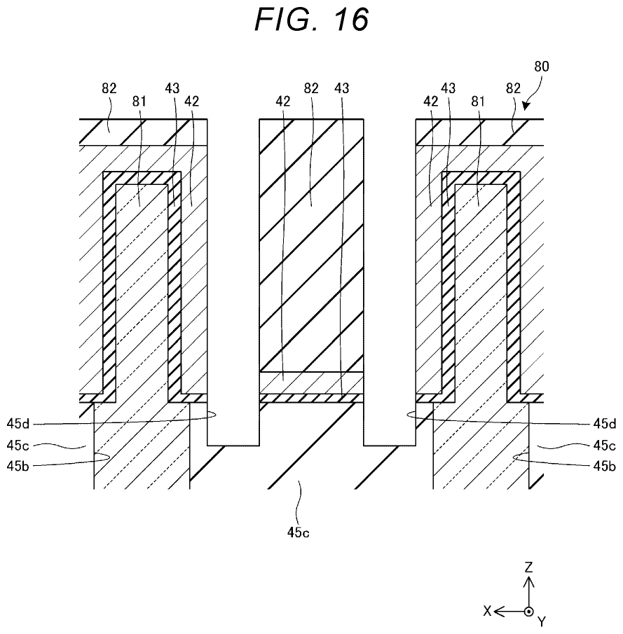

Next, as shown in FIGS. 15 and 16, the insulating layer 82, the conductive layer 42, the gate insulating film 43, and the insulating layer 45c in the portion in which the mask material 83 is open are removed by reactive ion etching. Accordingly, a plurality of groove portions 45d which extend along the Y-axis direction and in which the upper side is open are formed. The plurality of groove portions 45d divide the conductive layer 42 in the X-axis direction, and a portion that serves as a word line extending along the Y-axis direction is formed. Then, the mask material 83 is removed.

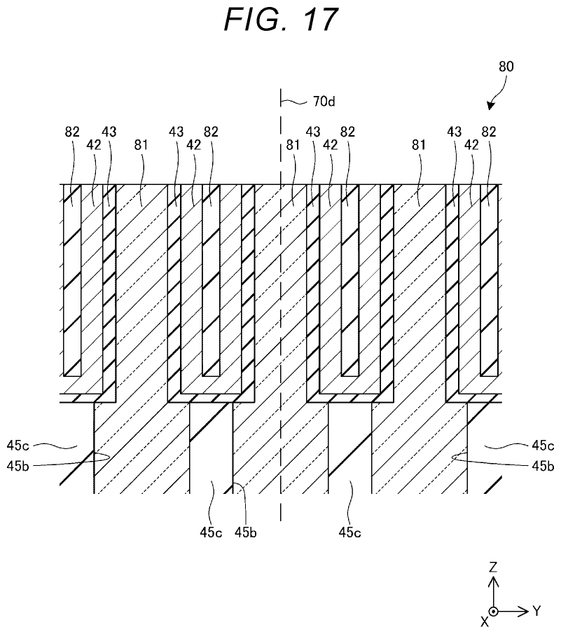

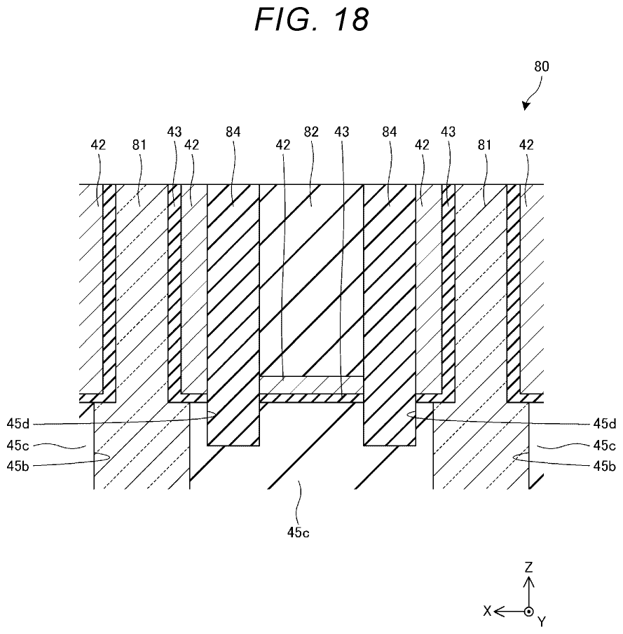

Next, as shown in FIGS. 17 and 18, the WL-embedded insulating film 84 made of SiO2, SiOC, or the like is formed in the plurality of groove portions 45d. Then, the surface of the semiconductor chip 80 is subjected to chemical mechanical polishing.

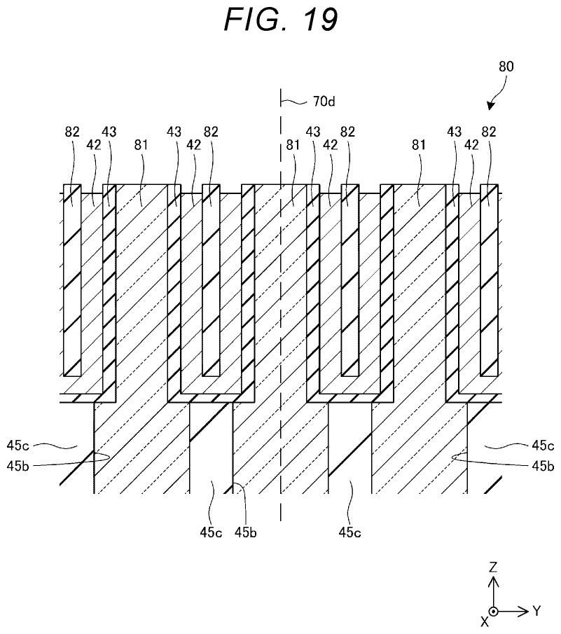

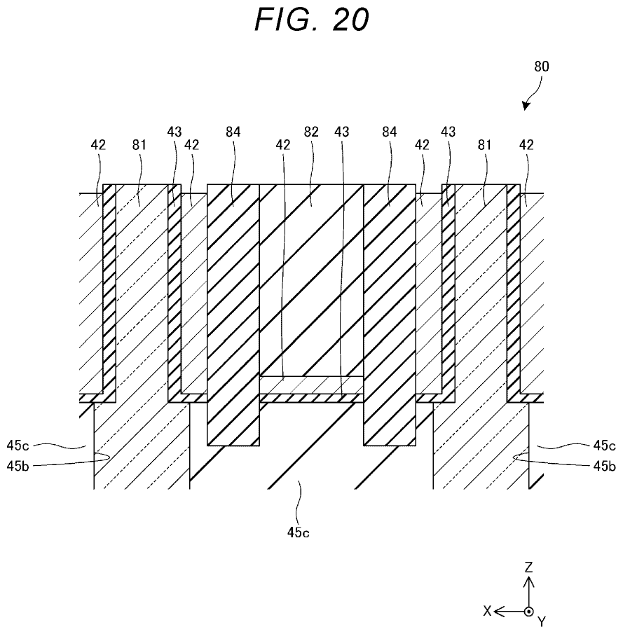

Next, as shown in FIGS. 19 and 20, the conductive layer 42 is etched. Accordingly, a part of the conductive layer 42 on the upper side is removed.

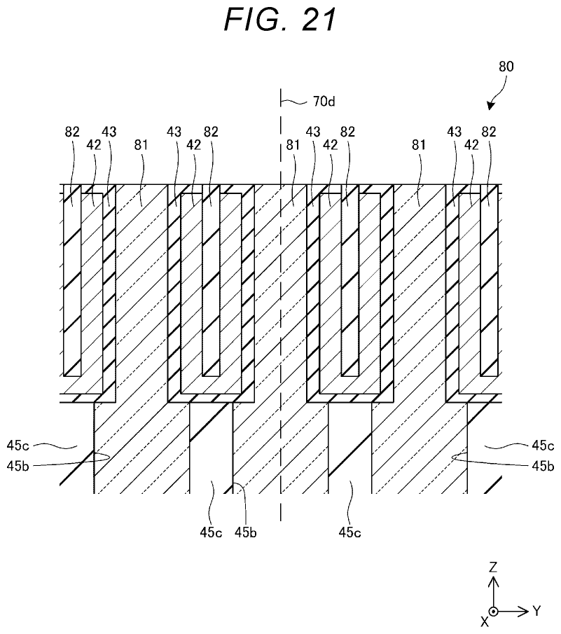

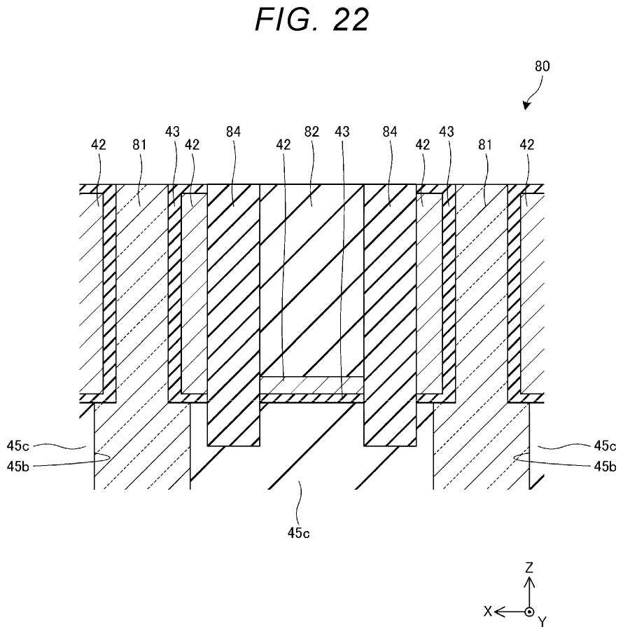

Next, as shown in FIGS. 21 and 22, an insulating film is formed on the upper side of the conductive layer 42 to form a gate insulating film 43 that surrounds the conductive layer 42. Then, the surface of the semiconductor chip 80 is subjected to chemical mechanical polishing.

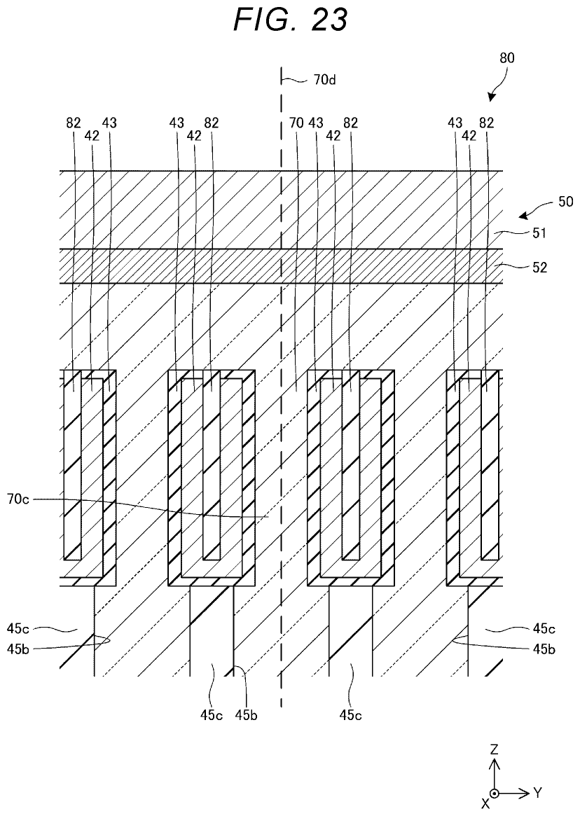

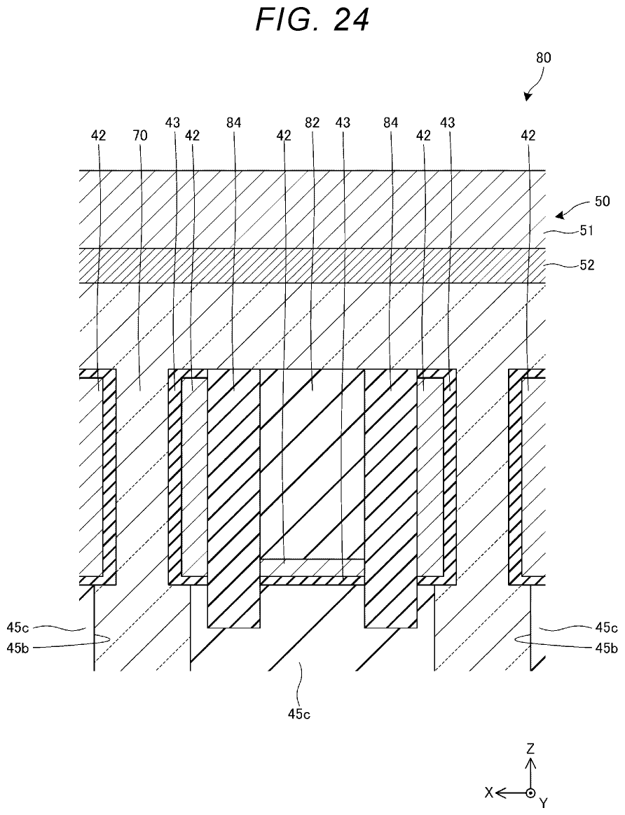

Next, as shown in FIGS. 23 and 24, the sacrificial amorphous silicon layer 81 is removed by etching, and the oxide semiconductor layer 70 is formed in the space where the sacrificial amorphous silicon layer 81 was originally present. Then, the ITO layer 52 and the conductive layer 51 are formed in this order on the upper side of the surface of the semiconductor chip 80.

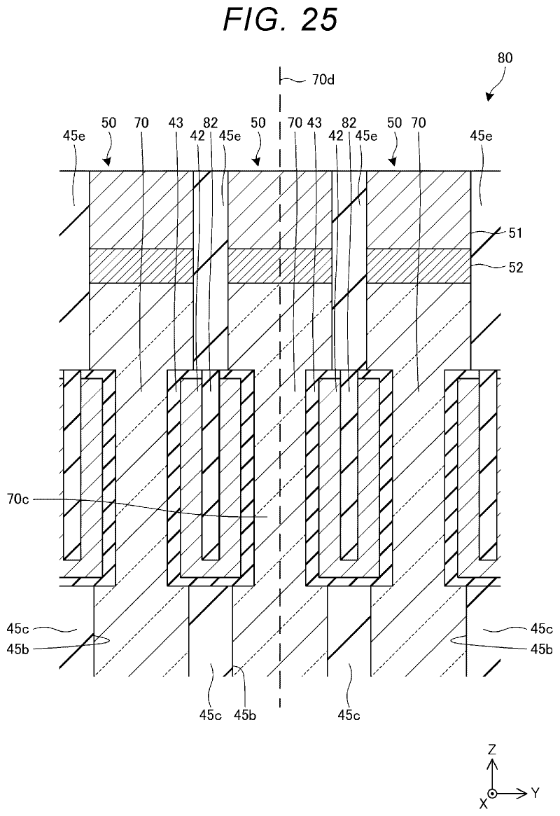

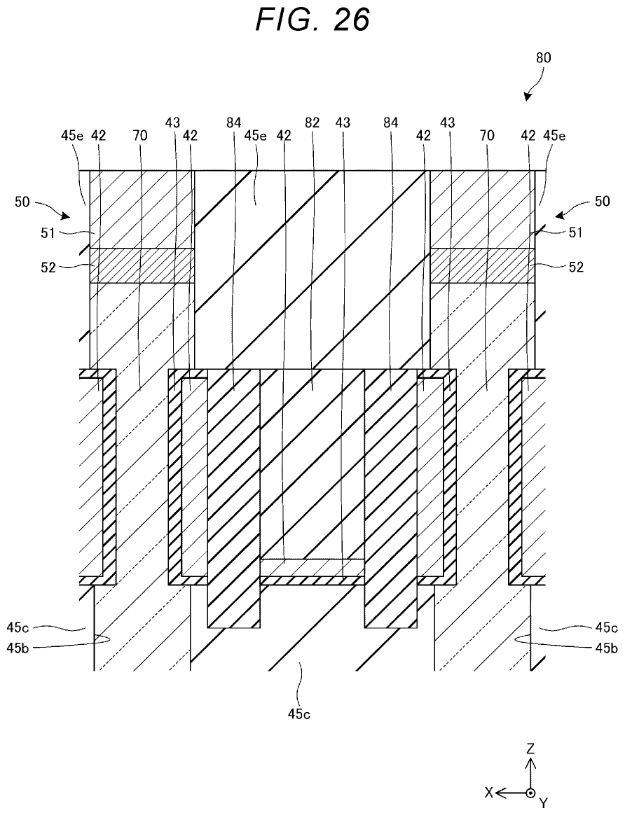

Next, as shown in FIGS. 25 and 26, the upper electrode 50 that is a landing pad is formed on the upper side of the oxide semiconductor layer 70. Specifically, the conductive layer 51, the ITO layer 52, and the oxide semiconductor layer 70 are removed by photolithography and reactive ion etching, leaving a portion where the landing pad is formed. The insulating layer 45e is formed in the space where the removed conductive layer 51, the ITO layer 52, and the oxide semiconductor layer 70 were originally present. The insulating layer 45e is provided with a part of the insulating layer 45 on the upper side (see FIG. 3). Then, the surface of the semiconductor chip 80 is subjected to chemical mechanical polishing. After the oxide semiconductor layer 70 is patterned, the insulating layer 45e may be formed around the oxide semiconductor layer 70, and then the ITO layer 52 and the conductive layer 51 may be formed and patterned to form the upper electrode 50.

### Effect

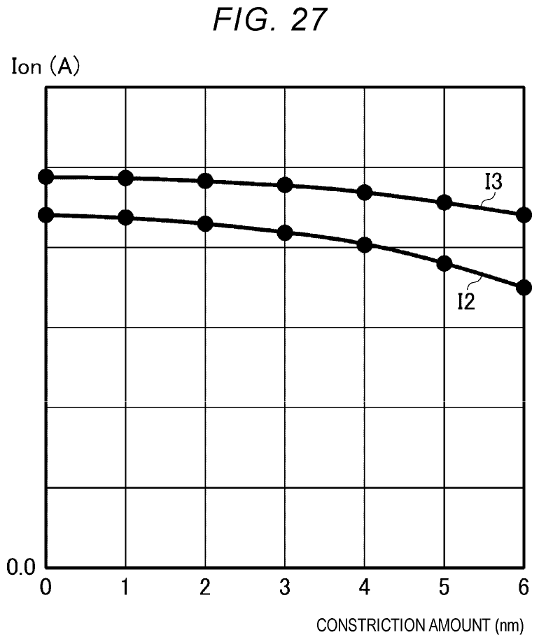

FIG. 27 is a diagram showing a change with respect to the constriction amount in the on-state current Ion flowing on the surface of the oxide semiconductor layer according to the first embodiment. The vertical axis indicates the on-state current Ion with a unit of “A” in a logarithmic scale. The horizontal axis indicates the constriction amount with a unit of “nm”. The simulation of the on-state current Ion was performed under a condition in which a TiO layer (not shown in FIGS. 2 and 3) having a resistance value of 150 kΩ was provided between the conductive layer 51 and the ITO layer 52.

The constriction amount is, for example, a difference (hereinafter, may be referred to as a first difference) between the radius (i.e., the minor or major radius) of the horizontal cross section at the first end 701 on the lower side of the portion 71 and the radius (i.e., the minor or major radius) of the horizontal cross section at the second end 702 on the upper side of the portion 72. Specifically, it is a value obtained by dividing a value obtained by subtracting w3 from w2 by 2. The constriction amount may be a difference (hereinafter, referred to as a second difference) between the radius (i.e., the minor or major radius) at the fourth end 704 on the upper side of the portion 74 and the radius (i.e., the minor or major radius) at the third end 703 on the lower side of the portion 72. The second difference is specifically a value obtained by dividing a value obtained by subtracting w4 from w5 by 2. In the present embodiment, the first difference and the second difference are the same.

As shown in FIG. 27, the current changes 12 and 13 respectively show changes with respect to the constriction amount in on-state current Ion when the voltage applied to the conductive layer 42 corresponding to the gate electrode is 2 volts and 3 volts. When the constriction amount is increased, the channel becomes thinner, so that the electric resistance of the portion 73 in the oxide semiconductor layer 70 is increased, but the decrease in the on-state current Ion is reduced.

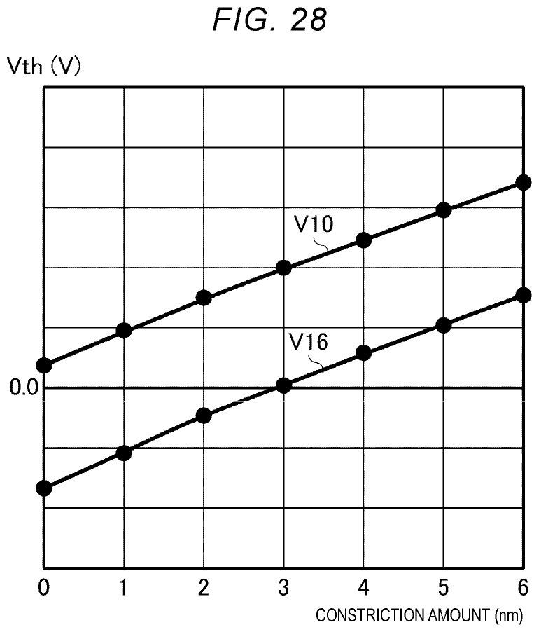

FIG. 28 is a diagram showing a change with respect to the constriction amount in the threshold voltage of the field effect transistor according to the first embodiment. The vertical axis indicates a threshold voltage Vth having a unit of “V”. The horizontal axis indicates the constriction amount with a unit of “nm”. The threshold voltage Vth is a voltage of the gate electrode required to cause a predetermined current to flow through the oxide semiconductor layer 70.

As shown in FIG. 28, the voltage changes V10 and V16 respectively indicate changes with respect to the constriction amount in the threshold voltage Vth required to cause currents of 10-10 A and 10-16 A to flow through the oxide semiconductor layer 70.

When the constriction amount is zero, the normally-on characteristic, in which a current flows even when the voltage applied to the conductive layer 42 corresponding to the gate electrode is zero volts, is provided. When the constriction amount is increased, the channel becomes thinner, and thus the depletion layer becomes thinner, and the threshold voltage Vth can be increased. That is, since the threshold voltage Vth can be increased from zero volts by increasing the constriction amount (for example, 3 nm or more), the field effect transistor 40 having the normally-off characteristics can be realized.

In addition, the contact area between the ITO layer 52 and the portion 71 can be increased by a configuration in which the horizontal width of the portion 71 in contact with the ITO layer 52 is made larger than the horizontal width of the portion 73, instead of uniformly reducing the horizontal width of the oxide semiconductor layer 70. Accordingly, the contact resistance between the ITO layer 52 and the portion 71, that is, the upper end 70a of the oxide semiconductor layer 70 can be reduced.

Similarly, for example, the contact area between the ITO layer 32 and the portion 74 can be increased by a configuration in which the horizontal width of the portion 74 in contact with the ITO layer 32 is larger than the horizontal width of the portion 73. As a result, the contact resistance between the ITO layer 32 and the portion 74, that is, the lower end 70b of the oxide semiconductor layer 70 can be reduced.

### SECOND EMBODIMENT

A field effect transistor 140 according to a second embodiment will be described. In the following second embodiment and later, the description of matters common to the first embodiment will be omitted, and only different points will be described. In particular, the same effects of the same configurations will not be successively described for each embodiment.

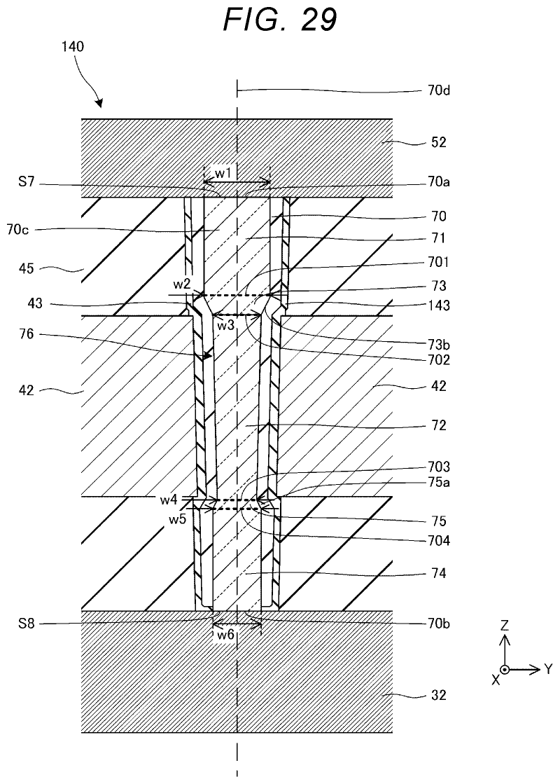

As shown in FIG. 29, the field effect transistor 140 is different from the field effect transistor 40 according to the first embodiment in that the gate insulating film 143 is in contact with the ITO layers 32 and 52, as compared with the field effect transistor 40 shown in FIG. 3.

In the present embodiment, the gate insulating film 143 has a tubular shape. That is, the horizontal cross section of the gate insulating film 143 parallel to the XY plane has a ring shape. The upper end and the lower end of the gate insulating film 143 are in contact with the ITO layers 52 and 32, respectively.

The oxide semiconductor layer 70 is provided inside the gate insulating film 143. In the present embodiment, the portion 73 of the oxide semiconductor layer 70 has a tapered surface 73b that is tapered toward the lower side.

### Manufacturing Method of Semiconductor Device

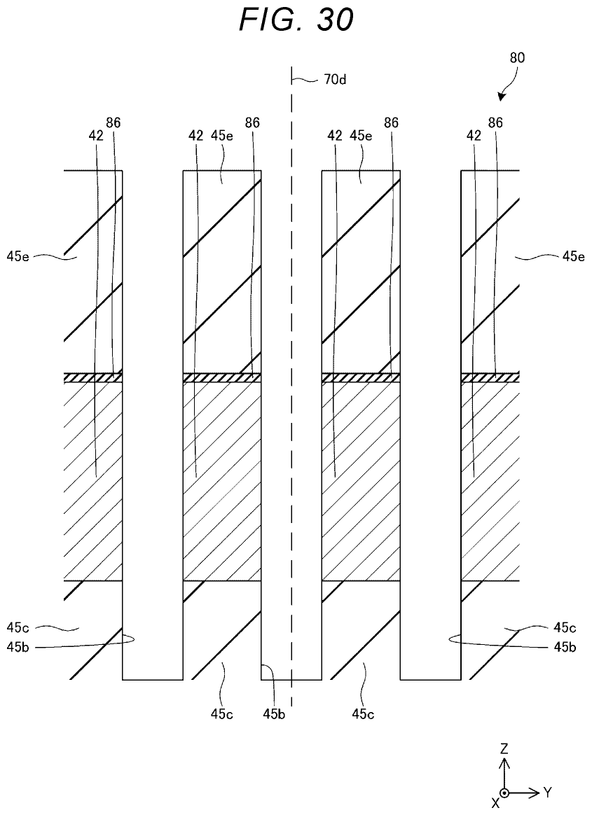

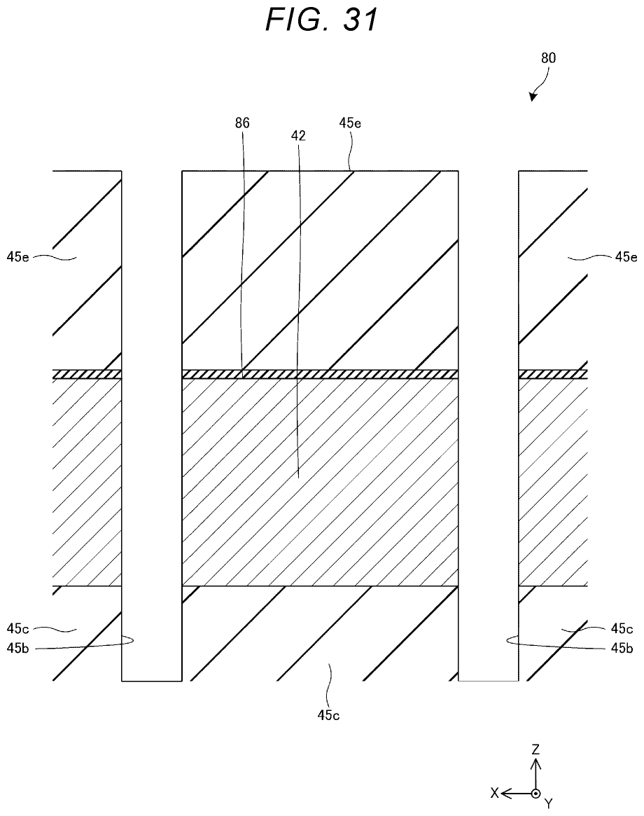

Hereinafter, a manufacturing method of the semiconductor device 30 will be described as an example of the manufacturing method of the semiconductor device according to the second embodiment. In FIGS. 30, 32, 34, 36, 38, and 40, cross-sectional views taken along the cutting-line A-A shown in FIG. 4 are shown. In FIGS. 31, 33, 35, 37, 38, 39, and 41, cross-sectional views taken along the cutting-line B-B shown in FIG. 4 are shown.

First, as shown in FIGS. 30 and 31, an insulating layer 45c, a conductive layer 42, an insulating layer 86, and an insulating layer 45e are formed on the surface of the semiconductor chip 80 on the upper side from the lower side to the upper side. In addition, a hole portion 45b in which the upper side is open by reactive ion etching is formed in the semiconductor chip 80.

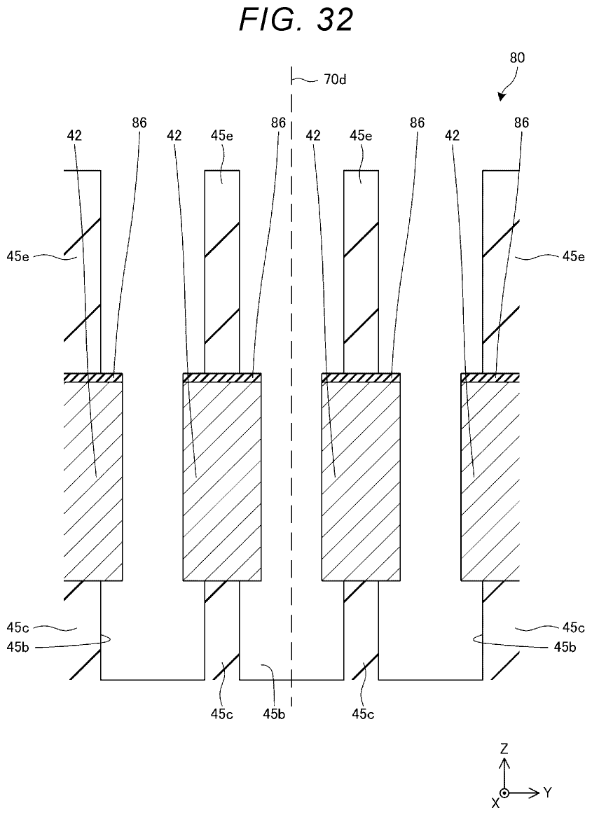

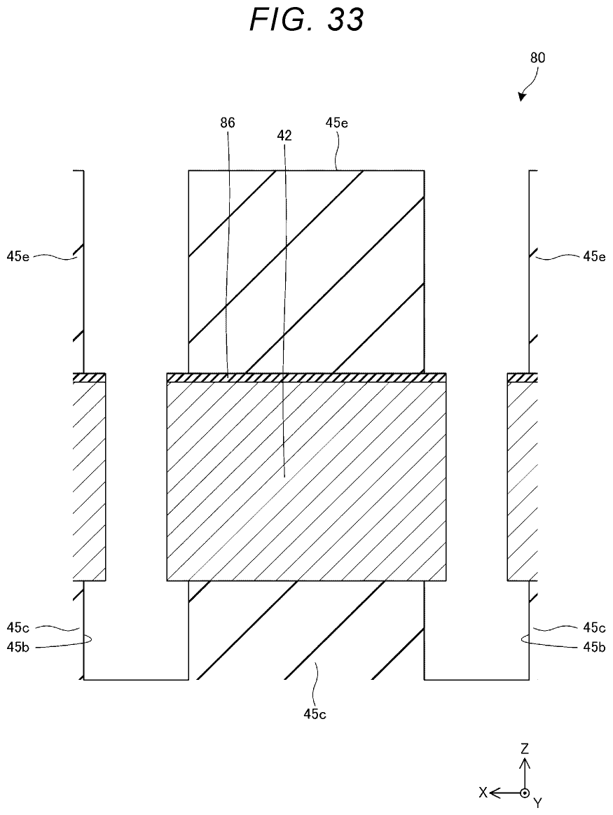

Next, as shown in FIGS. 32 and 33, the diameters of the hole portions 45b in the insulating layers 45c and 45e are increased by RIE post wet in which the insulating layers 45c and 45e are etched using a fluorine-based chemical solution.

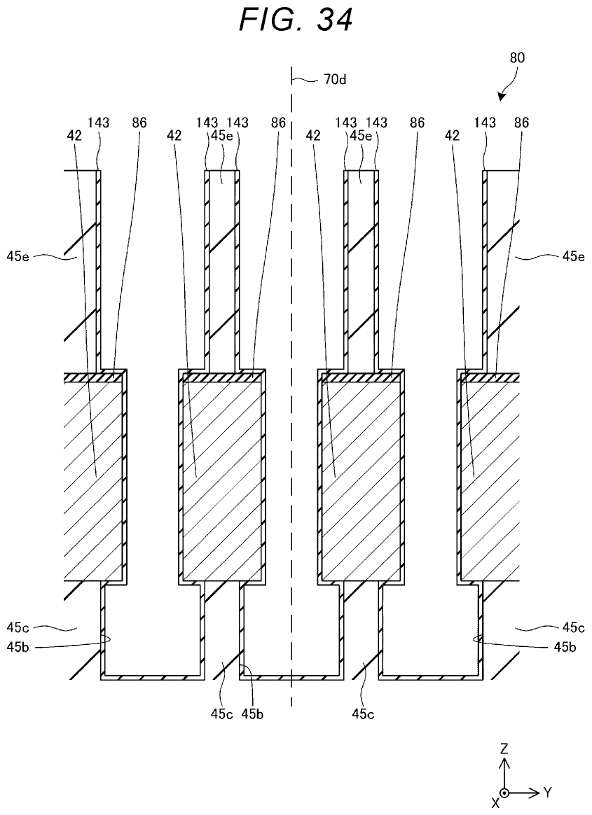

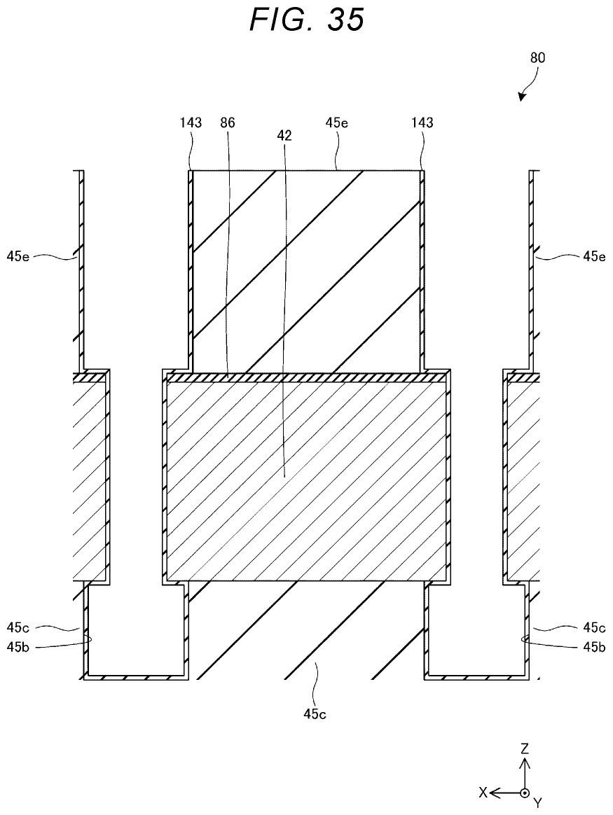

Next, as shown in FIGS. 34 and 35, the gate insulating film 143 is formed on the inner wall of the hole portion 45b.

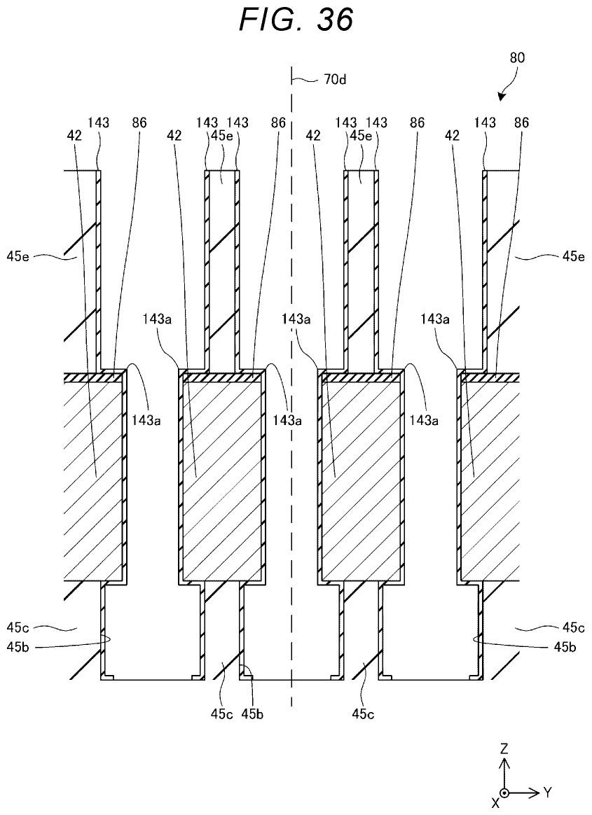

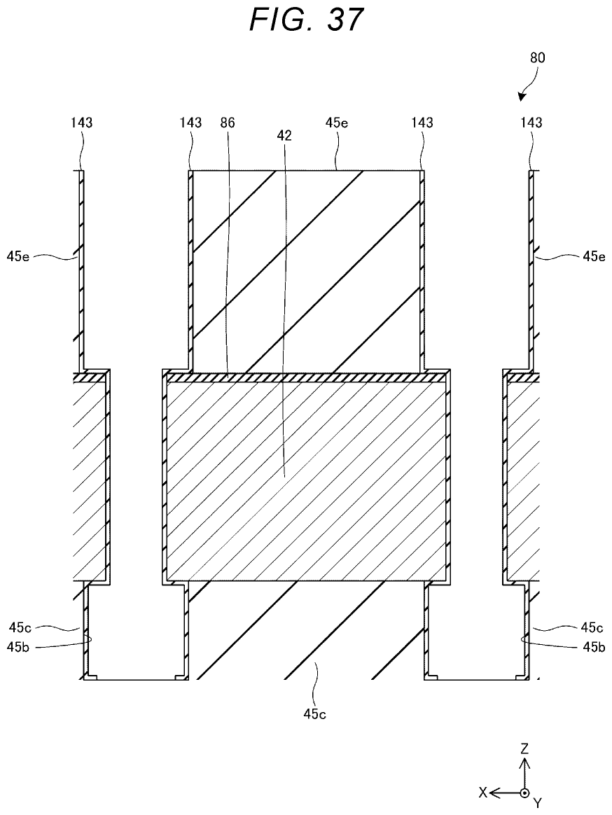

Next, as shown in FIGS. 36 and 37, the gate insulating film 143 at the bottom of the hole portion 45b is removed by reactive ion etching.

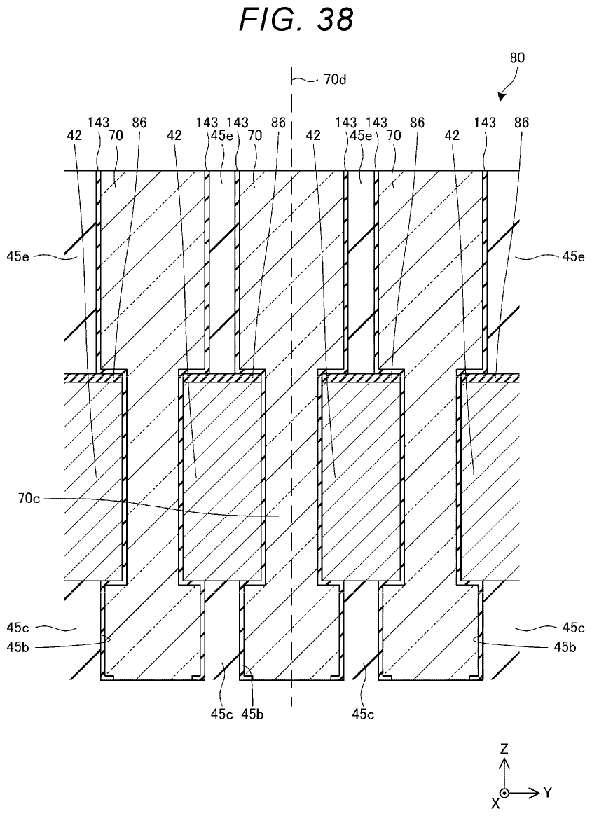

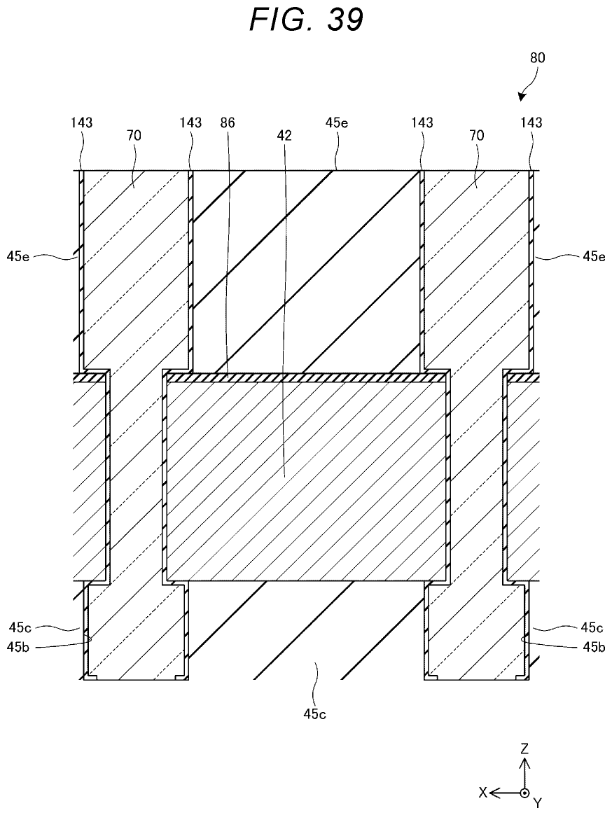

Next, as shown in FIGS. 38 and 39, the oxide semiconductor layer 70 is formed in the internal space of the hole portion 45b. Then, the surface of the semiconductor chip 80 is subjected to chemical mechanical polishing.

Next, the upper electrode 50 is formed on the upper side of the oxide semiconductor layer 70 (see FIGS. 23 to 26).

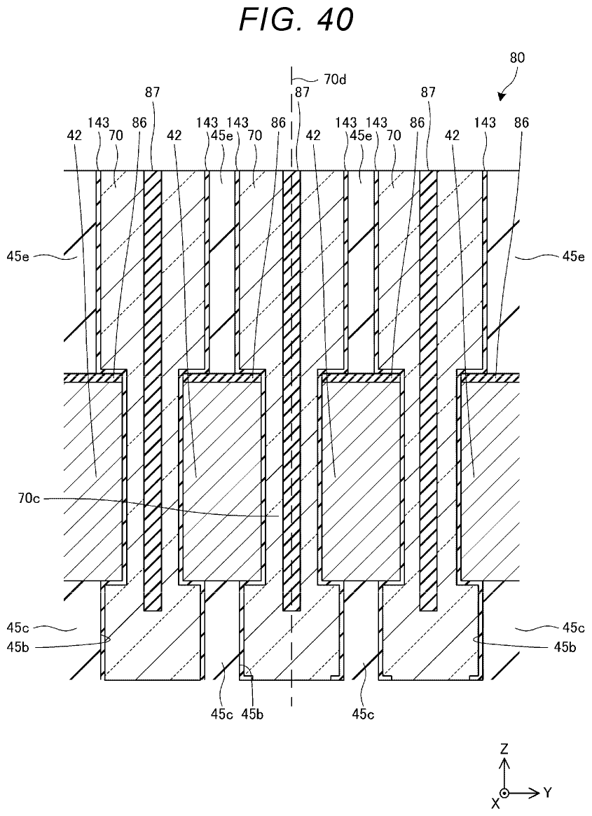

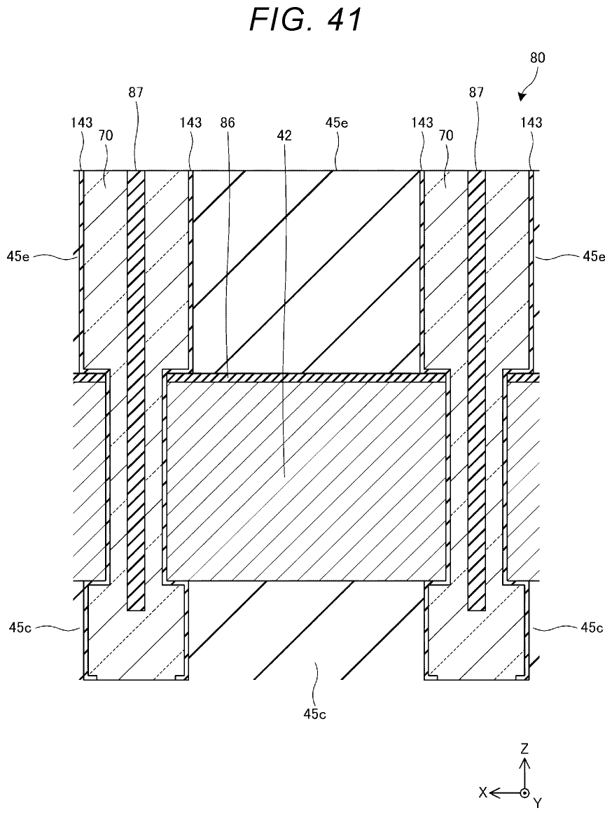

As shown in FIGS. 40 and 41, a core insulating film 87 extending in the up-down direction may be formed inside the oxide semiconductor layer 70. The structure in FIGS. 40 and 41 can be formed by embedding the oxide semiconductor layer 70 and the core insulating film 87 in this order in the internal space of the hole portion 45b.

In this way, since the core insulating film 87 is formed inside the oxide semiconductor layer 70, the gap can be filled, and thus the generation of voids can be inhibited. In addition, oxygen can be supplied to the oxide semiconductor layer 70 through the core insulating film 87.

In addition, at the time of the reactive ion etching shown in FIGS. 36 and 37, the gate insulating film 143 in contact with the surface on the upper side of the insulating layer 86 is also easily removed. In particular, the corner portion 143a of the gate insulating film 143 in contact with the surface on the upper side of the insulating layer 86 is easily removed. On the other hand, by forming the insulating layer 86 on the upper side of the conductive layer 42, the exposure of the conductive layer 42 can be inhibited even when the corner portions 143a of the gate insulating film 143 are removed. As a result, the possibility that the oxide semiconductor layer 70 and the conductive layer 42 are short-circuited can be reduced.

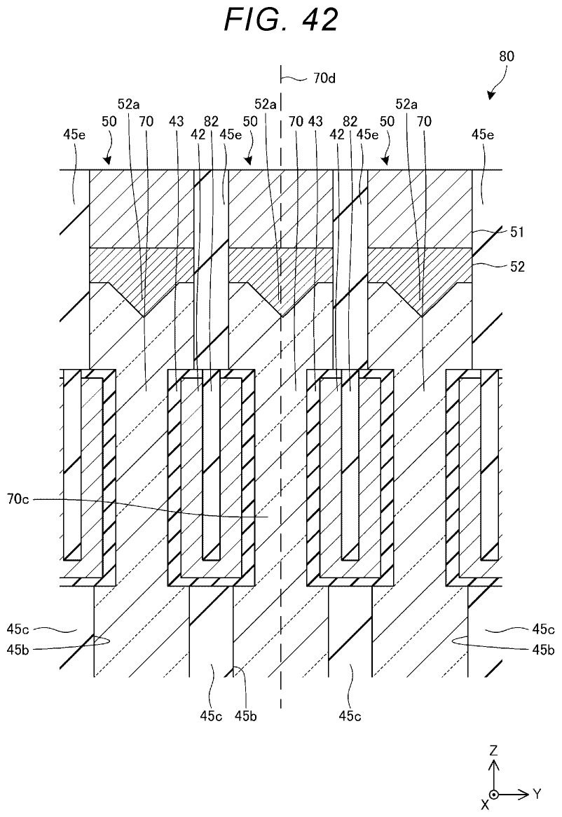

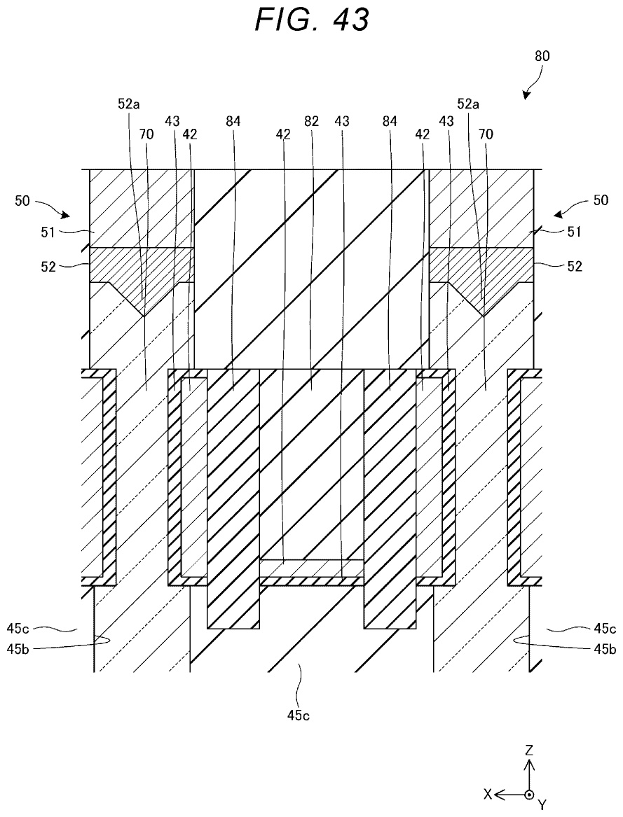

In addition, a core insulating film may be formed on the oxide semiconductor layer 70 shown in FIGS. 25 and 26. In this case, an insulating film may be interposed between the oxide semiconductor layer 70 and the ITO layer 52. On the other hand, as shown in FIGS. 42 and 43, a configuration in which a projection portion 52a that is pointed toward the lower side is formed on the surface on the lower side of the ITO layer 52 may be adopted. Accordingly, the contact resistance between the ITO layer 52 and the portion 71, that is, the upper end 70a of the oxide semiconductor layer 70 can be reduced. FIGS. 42 and 43 show cross-sectional views taken along the cutting-line A-A and the cutting-line B-B shown in FIG. 4.

(a) In the first embodiment and the second embodiment, the configurations of the oxide semiconductor layer 70 with the portions 71, 72, 73, 74, and 75 has been described, but the present disclosure is not limited thereto. The oxide semiconductor layer 70 may not have one of the portion 73 and the portion 75. In addition, the oxide semiconductor layer 70 may not have the portions 71 and 73 or the portions 74 and 75.

(b) In the first embodiment, the configuration in which the portion 73 has the stepped surface 73a substantially parallel to the XY plane has been described, but the present disclosure is not limited thereto. The portion 73 may have a configuration in which a tapered surface facing a lower side is provided.

(c) In the second embodiment, a configuration in which the portion 73 has the tapered surface 73b tapered toward the lower side has been described, but the present disclosure is not limited thereto. The portion 73 may have a configuration in which the stepped surface is substantially parallel to the XY plane.

(d) In the first embodiment and the second embodiment, the configuration in which the portion 75 has the tapered surface 75a has been described, but the present disclosure is not limited thereto. The portion 75 may have a configuration in which the stepped surface is substantially parallel to the XY plane.

(e) In the above-described embodiments, the configuration in which the field effect transistor 40 is a surrounding gate transistor (SGT) has been described, but the present disclosure is not limited thereto. The field effect transistor 40 may have a configuration having another structure such as a bottom-gate type structure.

(f) In the above-described embodiments, the configuration in which the field effect transistor 40 is used for the OS-RAM has been described, but the present disclosure is not limited thereto. The field effect transistor 40 can also be applied to a semiconductor device other than OS-RAM.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
an insulating layer;
an oxide semiconductor formed in the insulating layer and extending in a first direction;
a first electrode in contact with an upper end of the oxide semiconductor;
a second electrode in contact with a lower end of the oxide semiconductor; and
a gate electrode formed in the insulating layer and surrounding a part of the oxide semiconductor via an insulating film, wherein
the oxide semiconductor includes:
a first portion including the upper end of the oxide semiconductor,
a second portion between the first portion and the lower end of the oxide semiconductor, and
a first boundary portion between the first and second portions,
an upper end of the first portion has a first diameter,
a lower end of the first portion and an upper end of the first boundary portion have a second diameter equal to or smaller than the first diameter,
a lower end of the first boundary portion and an upper end of the second portion have a third diameter smaller than the second diameter,
a lower end of the second portion has a fourth diameter equal to or smaller than the third diameter, and
from the upper end of the oxide semiconductor toward the lower end thereof, a reduction rate of a diameter of the first boundary portion is larger than a reduction rate of a diameter of each of the first portion and the second portion.

2. The semiconductor device according to claim 1, wherein the first boundary portion has a first stepped surface facing a lower side thereof.

3. The semiconductor device according to claim 2, wherein the first stepped surface is formed in an annular shape when viewed from the lower side.

4. The semiconductor device according to claim 1, wherein the first boundary portion has a tapered shape tapering toward the lower end of the first boundary portion.

5. The semiconductor device according to claim 1, wherein a difference between the second and third diameters is 2 nm or more.

6. The semiconductor device according to claim 1, wherein
the oxide semiconductor includes:
a third portion including the lower end of the oxide semiconductor, and
a second boundary portion between the second and third portions, and
a lower end of the second boundary portion and an upper end of the third portion have a fifth diameter larger than the fourth diameter,
a lower end of the third portion has a sixth diameter equal to or smaller than the fifth diameter, and
a diameter of the second boundary portion increases in the first direction.

7. The semiconductor device according to claim 6, wherein the second boundary portion has a second stepped surface facing an upper side thereof.

8. The semiconductor device according to claim 7, wherein the second stepped surface is formed in an annular shape when viewed from the upper side.

9. The semiconductor device according to claim 6, wherein the second boundary portion has a tapered shape tapering toward the upper end of the second boundary portion.

10. The semiconductor device according to claim 6, wherein a difference between the fourth and fifth diameters is 2 nm or more.

11. The semiconductor device according to claim 6, wherein the gate electrode partly surrounds the second boundary portion.

12. The semiconductor device according to claim 6, wherein the gate electrode entirely surrounds the second boundary portion.

13. The semiconductor device according to claim 6, wherein the gate electrode does not surround the second boundary portion.

14. The semiconductor device according to claim 1, wherein the gate electrode partly surrounds the first boundary portion.

15. The semiconductor device according to claim 1, wherein the gate electrode entirely surrounds the first boundary portion.

16. The semiconductor device according to claim 1, wherein the gate electrode does not surround the first boundary portion.

17. A semiconductor device comprising:
an insulating layer;
an oxide semiconductor formed in the insulating layer and extending in a first direction;
a first electrode in contact with an upper end of the oxide semiconductor;
a second electrode in contact with a lower end of the oxide semiconductor; and
a gate electrode formed in the insulating layer and surrounding a part of the oxide semiconductor via an insulating film, wherein
the oxide semiconductor includes:
a first portion including the upper end of the oxide semiconductor,
a second portion between the first portion and the lower end of the oxide semiconductor,
a first boundary portion between the first and second portions,
a third portion including the lower end of the oxide semiconductor, and
a second boundary portion between the second and third portions,
in the first direction, an upper surface of the gate electrode is farther from the upper end of the oxide semiconductor than a lower end of the first portion, and a lower surface of the gate electrode is closer to the upper end of the oxide semiconductor than an upper end of the third portion,
an upper end of the first portion has a first diameter,
the lower end of the first portion and an upper end of the first boundary portion have a second diameter equal to or smaller than the first diameter,
a lower end of the first boundary portion and an upper end of the second portion have a third diameter smaller than the second diameter,
a lower end of the second portion and an upper end of the second boundary portion have a fourth diameter equal to or smaller than the third diameter,
a lower end of the second boundary portion and the upper end of the third portion have a fifth diameter larger than the fourth diameter, and
a lower end of the third portion has a sixth diameter equal to or smaller than the fifth diameter.

18. A semiconductor storage device comprising:
a semiconductor device including:
an insulating layer;
an oxide semiconductor formed in the insulating layer and extending in a first direction;
a first electrode in contact with an upper end of the oxide semiconductor;
a second electrode in contact with a lower end of the oxide semiconductor;
a gate electrode formed in the insulating layer and surrounding a part of the oxide semiconductor via an insulating film, wherein
the oxide semiconductor includes:
a first portion including the upper end of the oxide semiconductor,
a second portion between the first portion and the lower end of the oxide semiconductor, and
a first boundary portion between the first and second portions,
an upper end of the first portion has a first diameter,
a lower end of the first portion and an upper end of the first boundary portion have a second diameter equal to or smaller than the first diameter,
a lower end of the first boundary portion and an upper end of the second portion have a third diameter smaller than the second diameter,
a lower end of the second portion has a fourth diameter equal to or smaller than the third diameter, and
from the upper end of the oxide semiconductor toward the lower end thereof, a reduction rate of a diameter of the first boundary portion is larger than a reduction rate of a diameter of each of the first portion and the second portion;
a first capacitor electrode connected to either the first electrode or the second electrode;
a second capacitor electrode facing the first capacitor electrode; and
a dielectric film provided between the first and second capacitor electrodes.

19. The semiconductor storage device according to claim 18, wherein
the oxide semiconductor includes:
a third portion including the lower end of the oxide semiconductor, and
a second boundary portion between the second and third portions, and
a lower end of the second boundary portion and an upper end of the third portion have a fifth diameter larger than the fourth diameter,
a lower end of the third portion has a sixth diameter equal to or smaller than the fifth diameter, and
a diameter of the second boundary portion increases in the first direction.
